(19) United States
(12) Patent Application Publication
(10) Pub. No.: US 2005/0118349 A1
(43) Pub. Date: Jun. 2, 2005

(54) Layered structures

(76) Inventors: Andrew John Whitehead, Surrey (GB); Daniel James Twitchen, Berkshire (GB); Geoffrey Alan Scarsbrook, Berkshire (GB)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/494,368

(22) PCT Filed: Nov. 12, 2002
(86) PCT No.: PCT/IB02/04723

(30) Foreign Application Priority Data
Nov. 13, 2001 (GB) 0127263.2

(51) Int. Cl. C23C 14/00; C23C 16/00

(52) U.S. Cl. 427/523; 427/248.1

(57) ABSTRACT

A process of making a product which comprises at least two layers in contact with each other, each layer being of a wide-gap material and each layer differing from each other in at least one property, includes the steps of: (i) providing a substrate of a wide-band gap material having a surface and a region adjacent the surface having a particular characteristic, (ii) ion implanting the substrate through the surface to form a damaged layer below that surface, (iii) growing a layer of a wide-band gap material by chemical vapour deposition on at least a portion of the surface of the substrate through which ion implantation occurred, the material of the grown layer having a characteristic different to that of the region of the substrate adjacent the surface through which ion implantation occurred, and (iv) severing the substrate through the damaged layer. The wide-gap material is preferably diamond.

### BACKGROUND OF THE INVENTION

This invention relates to layered structures, particularly layered diamond structures.

For certain diamond applications, it is necessary to have two or more layers of diamond which have different properties in atomic contact with each other. One example is in electronics where a layered structures can be used to make a device, for example as described in WO 01/18882 A1

One method of making a layered diamond structure is by using ion implantation. Ions may be implanted into diamond to create an n-type or p-type semi-conducting layer on top of a layer with a different property. This method has the disadvantage that damage to the diamond occurs during ion implantation which can result in permanent degradation in important properties such as carrier lifetimes and mobilities. Further, the types and concentration of ions which can be successfully implanted in diamond are limited and the process often requires complex post implantation annealing.

Although chemical vapour deposition (CVD) provides a method of synthesising epi-layers, i.e. an epitaxially grown layer, to a desired thickness, the CVD process enables only a few very specific defects and impurities to be incorporated into the layer. This is best illustrated with the following example. A boron doped diamond layer can be grown onto a high purity single crystal substrate using a CVD process known in the art. The substrate might be processed from a natural diamond or diamond synthesised by CVD or high pressure high temperature (HPHT) methods. This will produce a two layer structure. Using conventional terminology this diamond structure will have pi-properties (i.e. properties exhibited by a sharp p-type to intrinsic semiconductor interface). Many of the typical two layer device structures that might be produced in this way require one of the layers to be very thin (<20 μm). For instance a 10 μm thick boron doped diamond layer on a 500 μm thick high purity diamond layer. A structure of this form, where precise thicknesses and sharp interfaces are necessary, requires considerable control of the synthesis process and/or careful mechanical processing of the structure following growth.

A CVD process is conducive to the synthesis of thin epi layers but has the disadvantage that only layers containing certain dopants can be synthesised. For example it is well known that HPHT synthesis provides a method of incorporating nickel, cobalt and nitrogen into the diamond in high concentrations (>5 parts per million (ppm) carbon atoms) but to date this has not been possible using CVD methods. Thus, to produce a diamond structure that consists of a thin epi-layer (<20 μm) containing nickel and a thicker boron doped layer (>100 μm) it would be necessary to take a suitably prepared substrate containing Ni with a thickness typically >200 μm (for ease of handling and processing) and then synthesise, using a CVD method, an overlayer (>100 μm) which contains the required boron concentration. Following growth, considerable care would then be needed with mechanical processing to finish with a structure which consists of, for example, a 10 μm Ni doped layer and a 100 μm B doped layer where the thickness tolerances are better than about 2 μm.

U.S. Pat. No. 5,587,210 describes a method of separating a CVD diamond layer from a diamond substrate. The method includes the steps of ion implanting a diamond substrate, thus creating a damaged layer of non-diamond carbon below the surface of the substrate through which ion implantation occurred, growing diamond on the surface of the substrate through which the ion implantation occurred, and electrochemically etching the diamond substrate to remove the damaged layer. The resulting product is a free standing CVD layer having a thin, i.e less than 1000 nm, layer of diamond bonded to a surface thereof.

The CVD diamond layer which is grown on the diamond substrate is pure CVD diamond. There is no suggestion that the CVD diamond layer should be doped or otherwise treated to change its electronic or other properties.

This US patent also suggests that the diamond substrate can be doped by ion implantation with suitable atoms to create n-type and p-type semi-conductors. When ion implanting a diamond substrate to create such semi-conductor properties, the implanted region will vary considerably in its dopant content. The region of highest and most uniform dopant concentration will lie below the surface through which ion implantation occurred. The region adjacent the surface through which the ion implantation occurred will contain little or no dopant and of non-uniform concentration. Thus, on either side of the interface between the substrate and the CVD diamond layer the material will be essentially pure diamond.

Furthermore, ion implantation doping is always associated with lattice damage due to the ion implantation, which substantially reduces the benefit obtained from the dopant in that it adversely modifies the electronic properties of the doped layer.

### SUMMARY OF THE INVENTION

According to the present invention, there is provided a process of making a product which comprises at least two layers in contact with each other, each layer being of a wide-band gap material and each layer differing from the other layer in at least one property, including the steps of:
(i) providing a substrate of a wide-band gap material having a surface and a region adjacent the surface having a particular characteristic,
(ii) ion implanting the substrate through the surface to form a damaged layer below that surface,
(iii) growing a layer of a wide-band gap material by chemical vapour deposition on at least a portion of the surface of the substrate through which ion implantation occurred, the material of the grown layer having a characteristic different to that of the region of the substrate adjacent the surface through which ion implantation occurred, and
(iv) severing the substrate through the damaged layer.

The ion implantation should be carried out with ions which allow deep penetration into the substrate, creating the damaged layer substantially below the surface through which the ion implantation occurs. The ions suitable to achieve this are typically ions of low atomic mass, preferably an atomic mass less than 21 and more preferably an atomic mass less than 13. Examples of suitable ions are helium and hydrogen ions. The ions for the ion implantation are preferably of high energy, e.g. have an energy exceeding 5 keV. The precise depth of the damaged layer can be accurately controlled by manipulating the energy and type (i.e. mass) of the implanted ions. Typically, the ion implantation dose will exceed 1×10¹⁵ cm⁻².

Generally, the damaged layer will lie at a depth of 0.05 to 200 μm, typically 0.3 to 10 μm, below the surface through which ion implantation occurred.

It is preferred that the region of the substrate between the surface through which ion implantation occurs and the damaged layer is substantially free of ion implantation doping damage.

The wide-band gap material may be silicon carbide, gallium nitride or the like and is preferably diamond.

Generally, the layers will differ from each other in the characteristic which provides the layers with different electrical properties. The product may comprise only two layers in contact with each other, or more than two layers. When the product consists of more than two layers, adjacent layers, in contact with each other, will have different characteristics. The interface between adjacent layers defines a sharp and well-defined interface between two regions having different properties. This is an important feature, particularly when the layered product is to be used in an electronic application.

The surface through which the ion implantation occurs may be planar or non-planar. Thus, the interface between adjacent layers may also be planar or non-planar. When non-planar, the profile may be designed to provide a specific useful feature for a device which includes the layered product as a component.

The substrate may be natural or synthetic diamond, particularly CVD diamond. The layer of grown wide-gap material may be CVD diamond or doped CVD diamond.

In one particular form of the invention, the region of the substrate adjacent to the surface through which ion implantation occurred is uniformly doped. The dopant may be selected from nitrogen, boron, nickel, cobalt, iron, phosphorus, sulphur or other elements which can occupy a lattice position, substitutional or otherwise, and provide the region with useful properties, particularly electronic properties.

The substrate and layer of grown wide-gap material may have the same thickness or differ in thickness. Generally, the layers will differ in thickness.

The process of the invention minimises excessive complicated post growth processing and enables structures that contain thin layers of diamond with properties very different to a second thicker layer to be synthesised. These structures have, for example, use in electronic applications.

### DESCRIPTION OF THE DRAWING

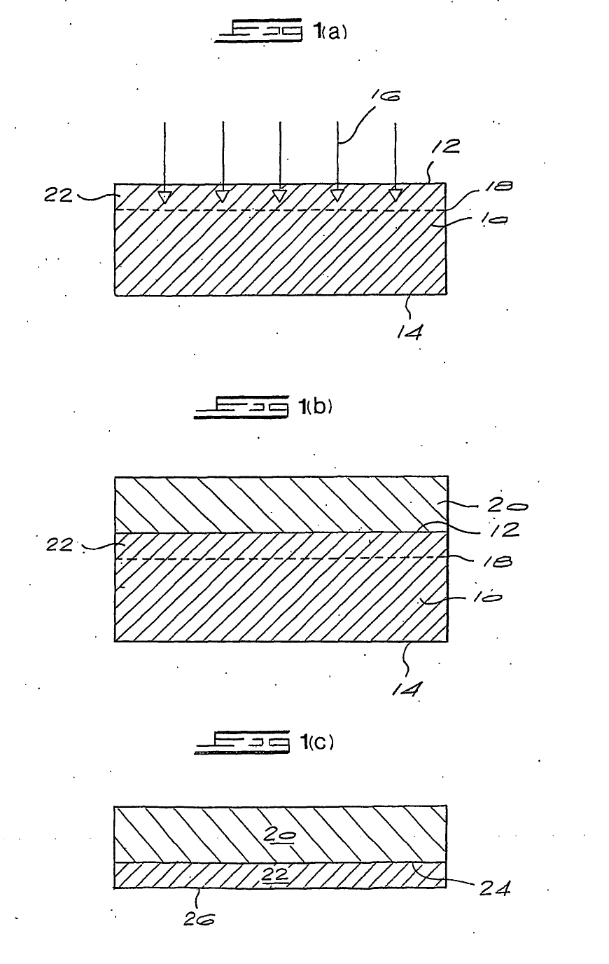

The drawing illustrates, as FIGS. 1(a) to 1(c), schematically the steps in an embodiment of the invention.

### DESCRIPTION OF EMBODIMENTS

The invention will now be illustrated with reference to the accompanying drawing. Referring to FIG. 1a, a diamond substrate 10 has an upper surface 12 and a lower surface 14. High energy ions are implanted in the diamond substrate 10 through surface 12, as illustrated by the arrows 16. The ions will typically be of light atoms such as hydrogen ions. The energy of the hydrogen ions will typically be between 20 keV and 5 MeV. The dose will typically be between 1×10¹⁵ cm⁻² and 1×10²⁰ cm⁻². The ions penetrate to a depth indicated by dotted line 18. The diamond region 22 between the layer 18 and the surface 12 is not significantly damaged because the collision cross-section of the implanted ions is low at higher energies but rapidly increases as they slow down. Thus the surface layer through which the ions are implanted suffers relatively little damage, with the majority of the damage being confined to the narrow damage layer (region 18) required for subsequent release. The depth of region 18 below surface 12 may be in the range 0.05 μm to 200 μm, and more typically in the range 0.3-10 μm.

The diamond substrate 10 may be natural, or synthesised by chemical vapour deposition (CVD) or by high pressure high temperature (HPHT) techniques. This diamond will have characteristic electronic properties associated with some specific incorporated defect. Selection of this diamond substrate from any source of diamond provides for the broadest possible range of dopants, impurities or defects within the diamond with which to tailor its properties. The diamond substrate surface may be flat, for example a polished surface, or it may be curved or have non-planar features such as trenches or raised features which may subsequently form elements of, for example, an electronic device structure. This latter possibility arises because the nature of ion implantation is to allow penetration of the ions down to a given depth, independent of the macroscopic variation in height of the substrate. This provides for device geometries that are not easily achieved in diamond by any other means. In one example of the invention, the dopant in the substrate may be present from growth of the diamond, e.g. nickel, cobalt or iron. As the dopant is present from growth of the substrate, the substrate diamond is free of the ion damage that would be associated with ion implantation doping, and the uniformity of the dopant is that of the original synthesis technique not the very non-uniform doping profile associated with ion implantation.

An epitaxial diamond layer 20 of different properties is then grown by CVD on the surface 12 of the substrate 10 (FIG. 1b). The conditions necessary to produce CVD diamond growth are well known in the art. The thickness of the layer 20 will typically be greater than the region 22 defined between the surface 12 and the damaged layer 18. This region will have a particular characteristic differing from that of the grown layer 20. When the characteristic is imparted to the region by a dopant, that dopant will be uniformly distributed through the region. The surface 12 thus provides a very sharp boundary between the properties of the overgrown layer 20 and that of the region 22.

The diamond substrate is then severed along region 18, by immersing the product into an acid etch, annealing or using appropriate electrochemical etching. The resulting product (FIG. 1c) is a layered product, in which diamond layer 20 has characteristics different to that of diamond layer 22. Interface 24 provides a sharp boundary between the characteristics of the two layers.

Implantation damage in the released layer 22 is generally low, since ion damage is low until the ion energy is almost exhausted which occurs as it reaches the damage layer 18. However, when using a substrate with a planar (preferably polished) surface, it is possible to reduce further the effect of this ion damage by implanting to a greater depth than is required (say to 5 μm), and after release removing a portion of the thickness of the released layer 22 by polishing, to leave a thinner final layer 22 (say 3 μm). This may be advantageous because the portion of diamond remaining had only higher energy ions traversing it, with proportionately lower ion damage, and the relatively heavily damaged region adjacent to the damaged region 18 is then wholly removed.

The process can be repeated more than once. For example bi-layer comprising the thin top layer 22 on a thicker layer 20 formed according to the invention can be further implanted through surface 26 of layer 22 into layer 20 to provide a damaged layer in layer 20. A thick CVD diamond layer is grown on surface 26 of layer 22 and then the sample severed along the implantation damaged layer. The result is a three layer structure, comprising the thin layer 22 sandwiched between a thin portion of the layer 20 and the new CVD diamond layer.

### EXAMPLE 1

A high purity diamond substrate produced using a CVD method known in the art with thickness 600 μm, is first implanted with 2 MeV oxygen ions to a dose of 1×10¹⁷ cm⁻². A thick (300 μm) boron doped single crystal CVD layer which has, as measured by SIMS, 2×10¹⁹ B atoms/cm⁻³ is grown on a surface of this substrate. Following growth the layered product is electrochemically etched to produce two samples: (i) a high purity diamond layer that can be reused and (ii) a two layer product consisting of a 1 μm high purity diamond layer and a 300 μm boron doped diamond layer in contact with the high purity diamond layer. This two layer product has an electronic application.

### EXAMPLE 2

A boron doped (1×10¹⁹ cm⁻³) diamond substrate prepared using a CVD method with thickness 620 μm is first implanted with 2 MeV hydrogen ions to a dose of 1×10¹⁹ cm⁻². A thick (300 μm) high purity single crystal CVD diamond layer is grown on to a surface of this substrate. Following growth the layered product is electrochemically etched to produce two samples: (i) a boron doped diamond plate which can be reused, and (ii) a two layer product consisting of a 10 μm boron doped diamond layer and a 300 μm high purity diamond layer. This two layer product has an electronic application.

1. A process of making a product which comprises at least two layers in contact with each other, each layer being of a wide-band gap material and each layer differing from the other layer in at least one property, including the steps of:
(i) providing a substrate of a wide-band gap material having a surface and a region adjacent the surface having a particular characteristic,
(ii) ion implanting the substrate through the surface to form a damaged layer below that surface,
(iii) growing a layer of a wide-band gap material by chemical vapour deposition on at least a portion of the surface of the substrate through which ion implantation occurred, the material of the grown layer having a characteristic different to that of the region of the substrate adjacent the surface through which ion implantation occurred, and
(iv) severing the substrate through the damaged layer.

2. A process according to claim 1 wherein the ions used in the ion implantation are ions of low atomic mass.

3. A process according to claim 1 wherein the ions used in the ion implantation have an atomic mass of less than 21.

4. A process according to claim 1 wherein the ions used in the ion implantation have an atomic mass of less than 13.

5. A process according to claim 1 wherein the ions are helium or hydrogen ions.

6. A process according to any one of the preceding claims wherein ions of high energy are used in the ion implantation.

7. A process according to any one of the preceding claims wherein the ions used in the ion implantation have an energy exceeding 5 keV.

8. A process according to any one of the preceding claims wherein the ion implantation dose exceeds 1×10¹⁵ cm⁻².

9. A process according to any one of the preceding claims wherein severing of the substrate through the damaged layer is achieved by acid etching, annealing or electrochemical etching

10. A process according to any one of the preceding claims wherein the damaged layer lies at a depth of 0.05 to 200 μm below the surface through which ion implantation occurred.

11. A process according to any one of the preceding claims wherein the damaged layer lies at a depth of 0.3 to 10 μm below the surface through ion implantation occurred.

12. A process according to any one of the preceding claims wherein the grown layer covers the entire surface of the substrate through which the ion implantation occurred.

13. A process according to any one of the preceding claims wherein the layers differ from each other in a characteristic which provides the layers with different electrical properties.

14. A process according to any one of the preceding claims wherein the wide band gap material is diamond.

15. A process according to any one of the preceding claims wherein the substrate is natural or synthetic diamond.

16. A process according to any one of the preceding claims wherein the substrate is CVD diamond.

17. A process according to any one of the preceding claims wherein the layer of grown wide-gap material is boron-doped diamond.

18. A process according to any one of the preceding claims wherein the region of the substrate adjacent the surface through which ion implantation occurred is uniformly doped.

19. A process according to claim 18 wherein the dopant is selected from nitrogen, boron, nickel, cobalt, iron, phosphorus and sulphur.

20. A process according to any one of the preceding claims wherein the substrate and layer of grown wide-gap material differ in thickness.

21. A process according to any one of the preceding claims wherein the surface through which ion implantation occurs is planar.

22. A process according to any one of the preceding claims wherein the surface through which ion implantation occurs is non-planar.

23. A process according to claim 1 substantially as herein described with reference to the accompanying drawing.

24. A process according to claim 1 substantially as herein described in either Example.
